(19) United States
(12) Patent Application Publication
(10) Pub. No.: US 2023/0258692 A1
(43) Pub. Date: Aug. 17, 2023

(54) SEAMLESS SPECTROGRAMS IN A MULTI-CHANNEL TEST AND MEASUREMENT INSTRUMENT

(71) Applicant: Tektronix, Inc., Beaverton, OR (US)

(72) Inventor: Gary J. Waldo, Hillsboro, OR (US)

(73) Assignee: Tektronix, Inc., Beaverton, OR (US)

(21) Appl. No.: 18/108,483

(22) Filed: Feb. 10, 2023

Related U.S. Application Data
(60) Provisional application No. 63/309,477, filed on Feb. 11, 2022.

(51) Int. Cl. G01R 13/02

(52) U.S. Cl. CPC G01R 13/0236; G01R 13/029; G01R 13/0272

(57) ABSTRACT

A test and measurement instrument includes a first channel input for accepting a first input signal, a second channel input for accepting a second input signal, a spectrogram processor for producing a first spectrogram from the first input signal and for producing a second spectrogram from the second input signal, and a display for simultaneously showing the first spectrogram and the second spectrogram. Methods are also described.

### CROSS-REFERENCE TO RELATED APPLICATIONS

This disclosure claims benefit of U.S. Provisional Application No. 63/309,477, titled “SEAMLESS SPECTROGRAMS IN A MULTI-CHANNEL TEST AND MEASUREMENT INSTRUMENT,” filed on Feb. 11, 2022, the disclosure of which is incorporated herein by reference in its entirety.

### TECHNICAL FIELD

This disclosure relates to test and measurement instruments, and more particularly to a test and measurement instrument having a display for showing various spectrograms of signals input to the instrument.

### BACKGROUND

Test and measurement instruments, such as oscilloscopes and spectrum analyzers, among others, measure characteristics of input signals being tested or measured and display them to a user, so that a user can visualize and inspect signal characteristics of interest. Measurements include signal characteristics in the time domain, such as voltage or current, and also in the frequency domain, such as spectral energy or power. Spectrograms are graphic displays that illustrate a specific type of frequency content, i.e., spectral content, of a signal or signals as they change over time. In general, a spectrogram is a collection of individual spectral traces from a waveform sample that are collected and processed over time, concatenated with one another to produce a single image, and then presented at an orthogonal angle from the original spectrum traces to allow the user to visualize particular characteristics or qualities of the input waveform as it changes over time. Generation of spectrograms is described in more detail below.

Traditionally, spectrograms found in oscilloscopes are assembled from many different acquisitions. There are problems with this approach though. First, there is a time gap between each slice of the spectrogram where the user does not know what was happening with the input signal. This is because there is always ‘blind’ time for an oscilloscope between each acquisition where the instrument is not acquiring any input signal. Second, the amount of time represented by each spectrum is typically a small portion of the overall time acquired in each oscilloscope acquisition. That time slice is referred to as Spectrum Time. A single spectrum is generated wherever Spectrum Time is located in the acquisition. Because of these two limitations, the actual amount of time represented in a traditional spectrogram may be only a very small percentage of overall input signal activity. Many debugging processes involve being able to view all signal activity over a user-specified period of time, something that isn’t possible with present devices, due to the time gaps between acquisitions described above.

Another limitation of existing tools that provide spectrograms is that present devices only provide spectrograms for a single input channel, and thus it is not possible to view spectrograms generated from multiple input signals simultaneously.

Embodiments according to this disclosure address these and other limitations in the field of test and measurement instruments.

### BRIEF DESCRIPTION OF THE DRAWINGS

FIG. 1 is a time diagram illustrating an example timing of acquisitions acquired by a conventional test and measurement instrument.

FIG. 2 is an illustration of how spectrograms of the type operated on by embodiments of the disclosure are produced.

FIG. 3 is a block diagram illustrating how a sampled input waveform acquisition is processed into individual spectral traces according to embodiments of the disclosure.

FIG. 4 is a block diagram illustrating how multiple spectral trace blocks are assembled to become a spectrogram, according to embodiments of the disclosure.

FIG. 5 illustrates an example spectrogram produced by the process outlined in FIG. 3, according to embodiments of the disclosure.

FIG. 6 is an example output display screen illustrating a spectrogram as well as a spectrum display, according to embodiments of the disclosure.

FIG. 7 is a block diagram of the example output display screen of FIG. 6 illustrating a user interface to change relative output sizes, according to embodiments of the disclosure.

FIG. 8 illustrates an effect of selecting a Spectrum Time that is less than a block time, according to embodiments of the disclosure.

FIG. 9 illustrates an example of creating a continuous spectrogram with overlap, according to embodiments of the disclosure.

FIG. 10 illustrates an example output screen showing spectrograms and spectrum displays for multiple channels, according to embodiments of the disclosure.

FIG. 11 illustrates another example output screen showing spectrograms and spectrum displays for multiple channels, according to embodiments of the disclosure.

FIG. 12 is a block diagram illustrating an example of how spectrograms and spectrum displays for multiple channels may be arranged, according to embodiments of the disclosure.

FIG. 13 is a block diagram of an instrument that includes automatic determination of spectrum and spectrogram attributes, according to embodiments of the disclosure.

### DETAILED DESCRIPTION

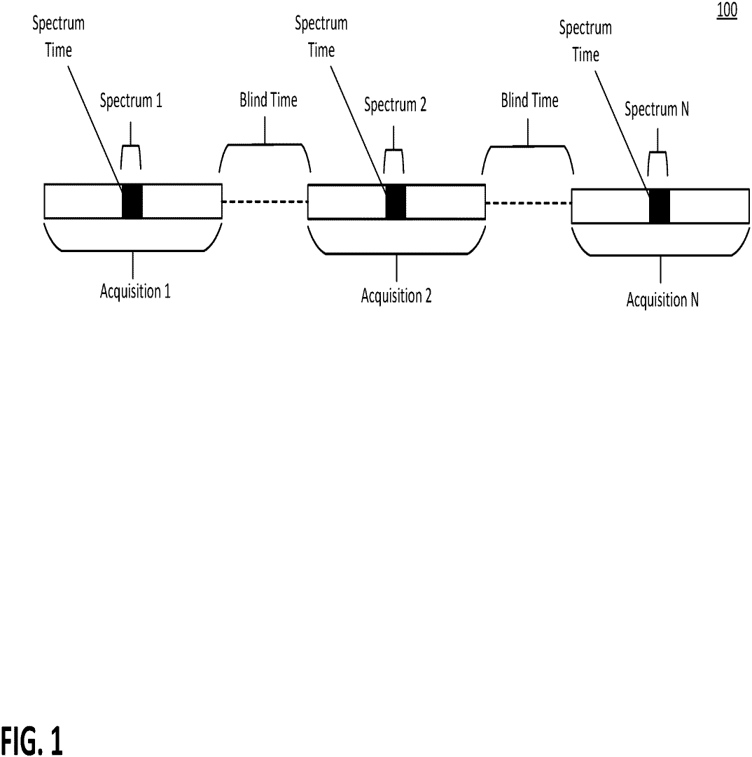

As described above, spectrograms are graphic displays produced by test and measurement instruments that illustrate spectral content of a signal or signals as they change over time. Also as described above, spectrograms found in oscilloscopes are generally assembled from many different acquisitions, such as illustrated in FIG. 1. This figure graphically illustrates an input channel of a test and measurement instrument. The input signal from a Device Under Test (DUT) connected to the input channel is received by the test and measurement instrument during acquisition times, labeled acquisition x, where x = 1, 2, ... N, in FIG. 1. Note that there are time gaps, labeled as blind times, between acquisitions. These blind times indicate that, although the DUT may be generating a signal during these blind times, the test and measurement instrument is not acquiring any input signals during the blind times. Blind times may be significant, meaning that there may be long periods of time between acquisitions that the test and measurement instrument is not recording any input signal.

Also illustrated in FIG. 1 is a time slice in each acquisition labeled as Spectrum Time, which indicates that the test and measurement instrument generates a spectrum display, labeled spectrum x, x = 1, 2, ... N, for only those periods of acquisition labeled as Spectrum Time. Thus, because of the blind times and because of the relatively small portion of an acquisition that is within the Spectrum Time, the amount of signal from the DUT that is actually displayed in a spectrogram display is quite small, which may lead to inaccurate conclusions of the DUT’s performance.

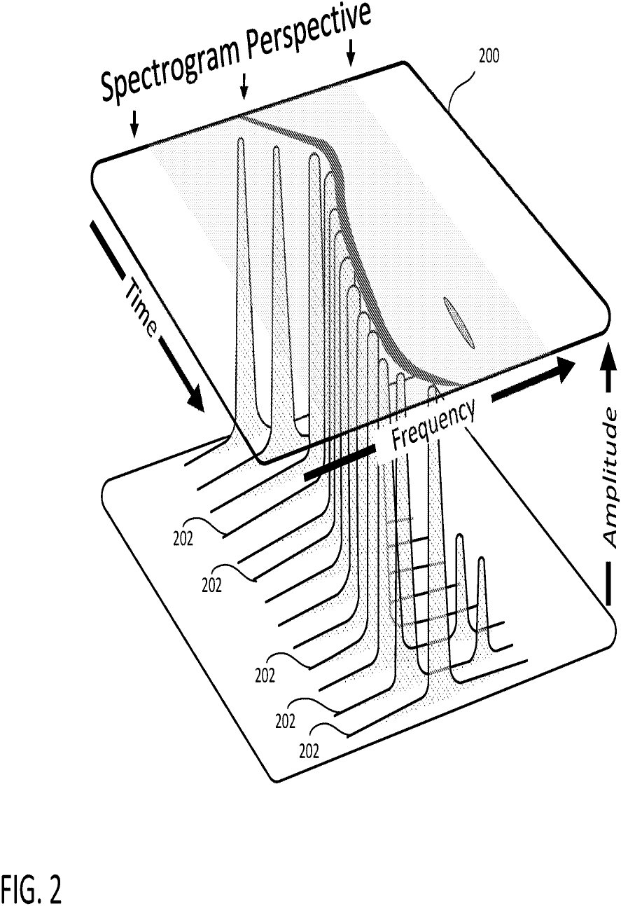

FIG. 2 describes spectrograms generated according to embodiments of the disclosure in more detail. In FIG. 2, an illustrated spectrogram 200 is a graphic image produced by generating a series of individual spectrum traces 202, concatenating the spectrum traces together, and then presenting the concatenated spectrum traces at an orthogonal angle from the original spectrum traces to allow the user to visualize particular characteristics or qualities of the input waveform as it changes over time. As illustrated in FIG. 2, each series of spectrum traces 202 spans a pre-defined frequency span, where the amplitude of the trace indicates received signal strength, i.e., power, for each of the individual frequencies covered in the span. Each individual spectrum trace represents the input signal strength captured over a period of time of the acquisition. After the first spectrum trace is generated, a subsequent trace is generated. If the input signal has changed between the time the first and second spectrum traces are generated, the second spectrum trace will vary from the first spectrum trace. The spectrogram 200 combines all of the generated spectrum traces 202 with one another as they are produced over time, where time is represented on the Y-axis of the spectrogram and frequency is represented on the X-axis of the spectrogram. When the newest spectrum traces appear at the top of the spectrogram image, it is referred to as a waterfall display spectrogram. Instead, when the oldest spectrum traces appear at the top of the spectrogram image, it is referred to as a reverse-waterfall configuration. The spectrogram itself is the view from the ‘top’ of this generated image, referred to in FIG. 2 as the spectrogram perspective. The spectrogram may be color coded to represent the amplitude or magnitude variations across the frequency span of the spectrum trace. With such a spectrogram image, the user may observe the static, dynamic, and transient nature of the spectral activity of the signal being analyzed. Although spectrograms produced by instruments are typically shown in color, the spectrogram of FIG. 2 is in greyscale, where darker portions of the spectrogram represent higher amplitudes or magnitudes.

Unlike the discontinuous spectrograms described with reference to FIG. 1, embodiments according to this disclosure produce continuous spectrograms. Continuous spectrograms are constructed from a single, continuous waveform acquisition of the input signal in instruments where an acquisition length of the input signal exceeds the amount of the spectrum being analyzed by Spectrum Time.

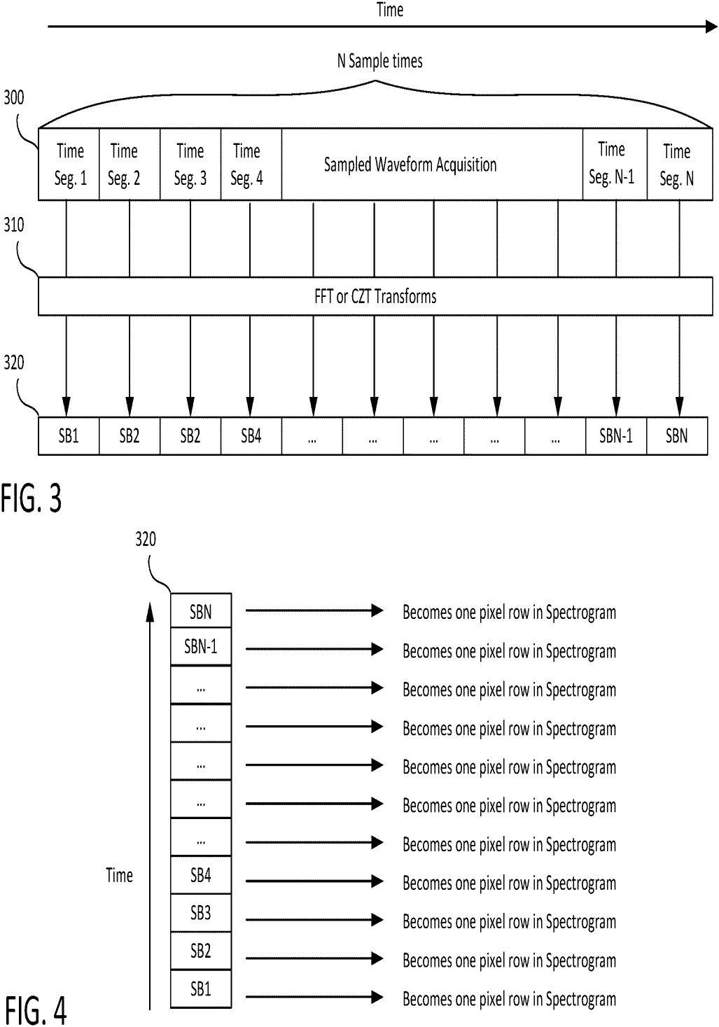

FIG. 3 illustrates a first series of steps for generating a continuous spectrogram image from an acquired input signal waveform, which was generated by a device being tested by the instrument, or Device Under Test (DUT). The total amount of time of the input signal acquired by the instrument is referred to as the acquisition time, and in FIG. 3 is represented as the total of all the individual time segments 1 - N of the acquisition 300. Spectrograms are generated by performing a time-to-frequency transform 310, such as a Fast Fourier Transform (FFT) or Chirp-Z Transform (CZT) of a time-delimited portion of the input signal acquisition 300 to create a series of spectrum traces 320. The series of spectrum traces 320 is formed from N number of individual spectrum blocks SB1, SB2, ..., SBN. Continuous spectrograms include spectrum traces for all portions of the input signal acquisition. Although variations are described below, in FIG. 3 it is assumed that the width of each spectrum block SB1, SB2, etc. is the same as the spectral width produced by the frequency transform 310, which may be controlled by a user setting a resolution bandwidth, as described below.

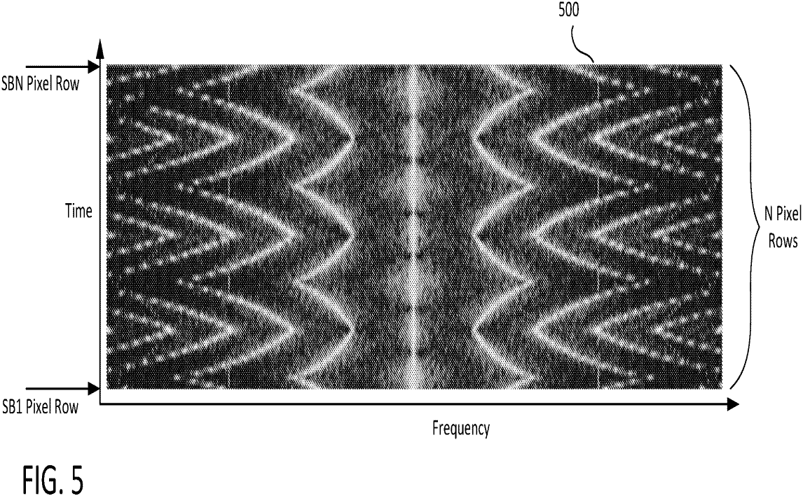

FIG. 4 illustrates how each spectral block SB1, SB2, etc. in the spectrum trace 320 is oriented to one another. Each spectral block SB1, SB2, etc. becomes one pixel row of the resultant spectrogram. And FIGS. 4 and 5 illustrate how the spectral blocks are assembled to create a spectrogram, such as the spectrogram 500 of FIG. 5. Note that in FIGS. 4 and 5, the oldest spectrum block, SB1, i.e., the first spectrum block generated, is placed at the bottom row of the spectrogram, as the spectrogram 500 of FIG. 5 is a waterfall spectrogram. Had the spectrogram 500 been a reverse-waterfall spectrogram, then the oldest spectrum block, SB1, would be placed at the top row of the spectrogram. As illustrated in FIG. 5, the spectrogram 500 includes N pixel rows, each of which correspond to a particular, individual, spectrum block SB1, SB2, etc. Also, as described above, the X-axis of the resultant spectrogram 500 measures frequency, while the Y-axis of the spectrogram measures time.

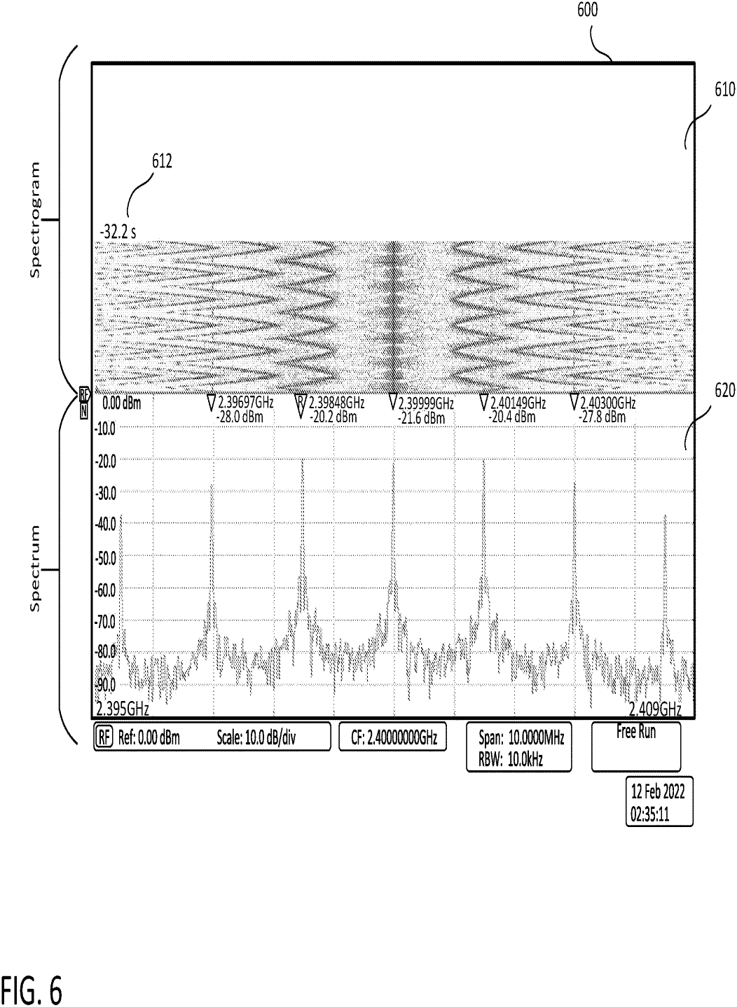

Oftentimes spectrograms, such as the spectrogram 500 of FIG. 5, are illustrated in conjunction with a spectral display of one of the time slices used to generate the spectrogram. FIG. 6 is an example output display screen 600 illustrating a spectrogram 610 as well as a spectral display or spectrum 620. Both of the spectrogram 610 and spectrum 620 have frequency as their x-axis, and span the same amount of frequency spectrum. As described above, the spectrum 620 has amplitude as its y-axis, while the spectrogram has time as its y-axis. A timestamp 612 reports that the spectrogram 600 was built from all of the spectrums acquired in the last 32.2 seconds, with the oldest being at the top of the spectrogram and the most recent being at the bottom. In this way, the spectrogram 600 shows a graphic display of the power or intensity of the input signal as it varies over time.

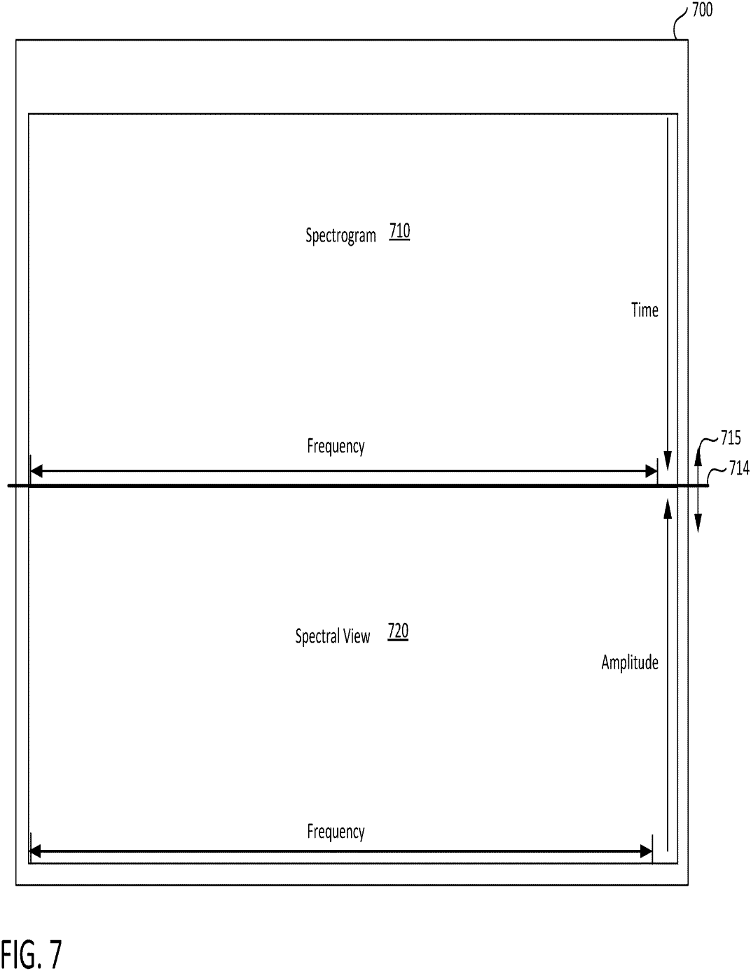

FIG. 7 is a block diagram of the example output display screen 700 illustrating a user interface to change relative output sizes of the display screen, according to embodiments of the disclosure. Similar to the display screen illustrated in FIG. 6, the example output display screen 700 includes a spectrogram 710 in an upper portion of the screen and a spectral view or spectrum 720 in a lower portion. The example display 700 includes a user interface that allows a user to control a relative size of the spectrogram 710 and spectrum 720. Specifically, a horizontal indicator 714 is controllable by the user, as indicated by reference 715, which indicates that the user may shift the relative position of the horizontal indicator 714. In response, the test and measurement instrument that generates the display screen 700 modifies the sizes of the spectrogram 710 and spectrum 720. Moving the horizontal indicator 714 upward, such as by dragging a mouse or controlling the movement by keyboard, causes the vertical size of the spectrum 720 to increase, while decreasing the vertical size of the spectrogram 710. Moving the horizontal indicator 714 downward causes the opposite effect. Embodiments that include multiple spectrograms and spectrums, described below, may have the same or similar user controls so that the user may customize the display screen.

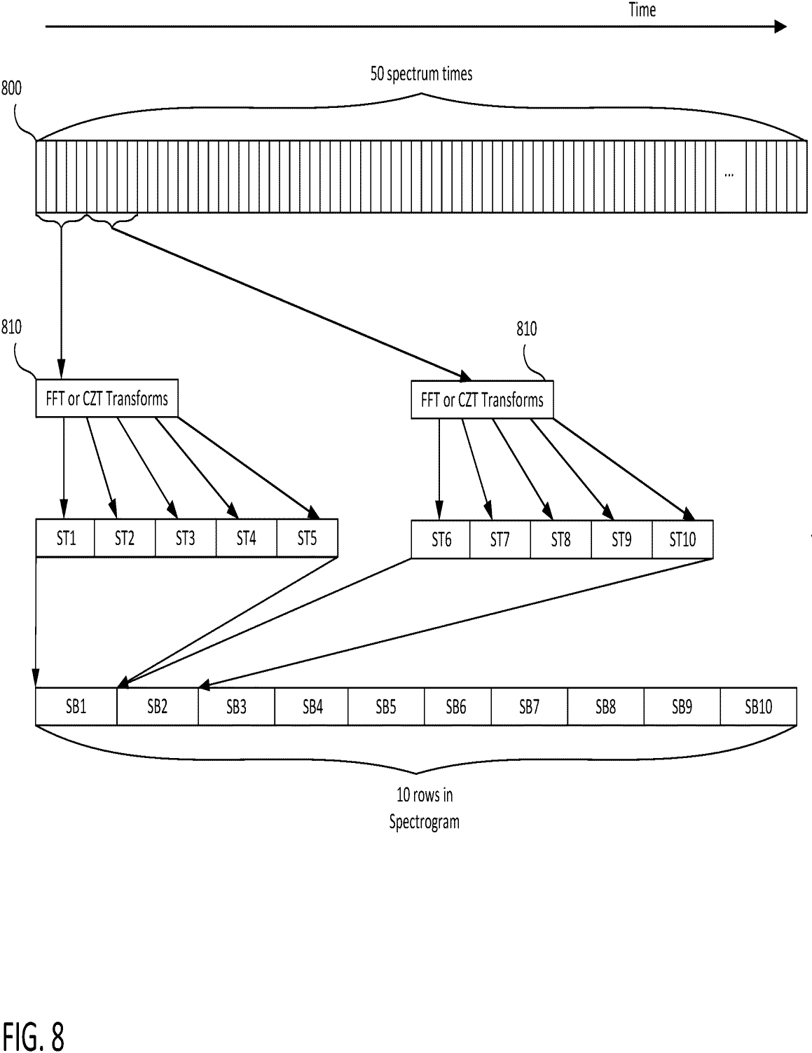

In FIG. 4, the individual spectrum blocks SB1, SB2 of FIG. 3 were assumed to have the same block width as the width produced by the transform 310, which is not always true. Instead, the width produced by the transform 310 may be larger or smaller than the width of the individual spectrum blocks. FIG. 8 illustrates case where the width of the Spectrum Time is less than the width of the individual spectrum blocks used to create a spectrogram.

With reference to FIG. 8, the Spectrum Time is 2% of the total width of an input signal acquisition 800, rather than 10% as in FIG. 3. So, this means that there are 50 total Spectrum Times contained within the input signal acquisition 800. But, assuming there are still ten rows of pixels in the ultimate generated spectrogram, with each row produced by one of the ten spectrum blocks SB1 – SB 10, this means that there will be five Spectrum Times combined into a single spectrum block. In general, the spectrum-time produced by a transform 810 is inversely proportional to the frequency resolution, or Resolution Bandwidth (RBW) and the selected Window type of the individual spectrum traces produced by the transform 810. Narrower RBW settings lead to longer Spectrum Times, while wider RBW settings result in shorter Spectrum Times. In one example, a 100 kHz RBW has a Spectrum Time of 22.3 µS, while a 10 kHz RBW has a Spectrum Time of 223 µS. The Spectrum Time therefore describes the length, in time, of the section of the original acquired input signal waveform used to generate the individual spectral traces used to create a single spectrum block. As illustrated in FIG. 8, five spectral traces, ST1, ST2, ST3, ST4, and ST5, produced by the transform 810 are combined to create the spectrum block SB1, which, as described above, becomes one row of pixels for the resultant spectrogram. Then the process advances to process the second spectrum block, SB2, where another five spectral traces, ST6, ST7, ST8, ST9, and ST10 produced by the transform 810 are combined to form the spectrum block SB2. Although not illustrated, this process continues with the remainder of the Spectrum Times in the acquired input signal acquisition 800 until all ten of the spectrum blocks SB1-SB10 are generated, and assembled, to become the spectrogram image. There are multiple techniques that may be used to combine multiple spectral traces, such as ST1 – ST5, into a single spectrum block, such as SB1. One such combination technique is processing the spectral traces by using max hold detection, for instance, which is a known technique in spectrum processing. Also, it is not necessary that the Spectrum Time be an exact integer multiple of a spectrum block time, but rather embodiments of the invention address this by overlapping the final Spectrum Time of a block into a subsequent spectrum block. Examples of such techniques are described in more detail below.

The examples described with reference to FIGS. 4, 5, and 8 all assume that the width of the spectrum blocks is the same or larger than the Spectrum Time, but there may be cases where the width of each of the spectrum blocks creating the spectrogram is less than the Spectrum Time, especially when the number of rows in the produced spectrogram grows large. Creating the spectrogram image with such conditions introduces the concept of ‘overlap’, which is described below.

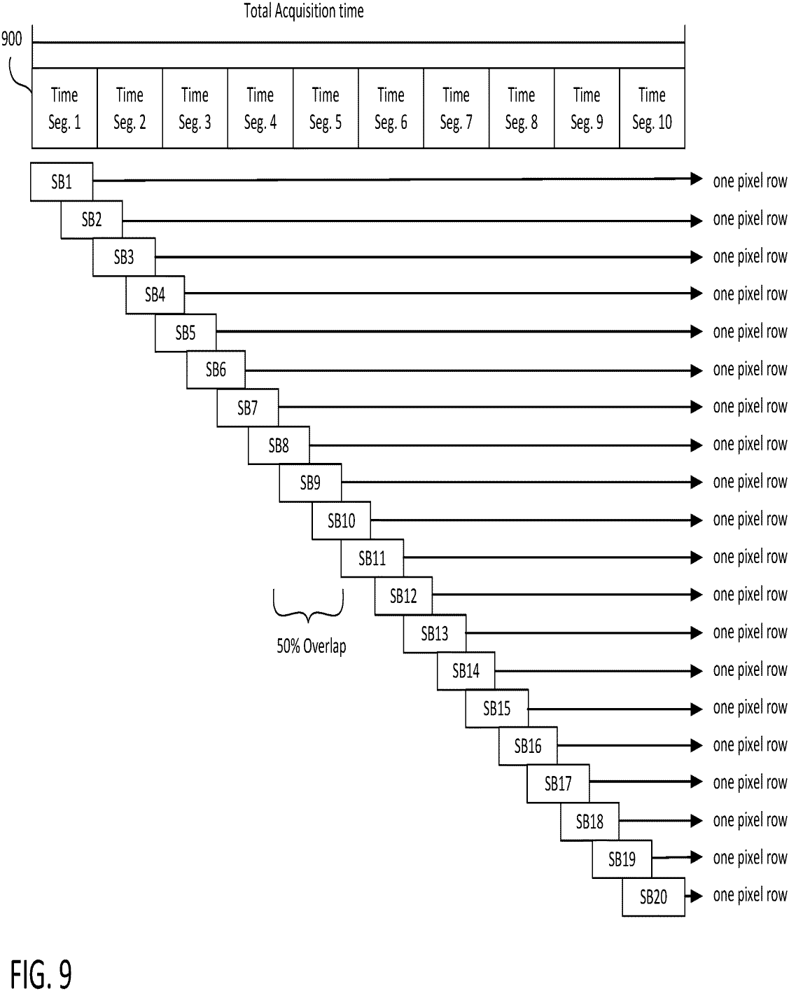

FIG. 9 illustrates an example where the Spectrum Time of an input signal waveform acquisition 900 is 10% of the total acquisition time, and where there are 20 available pixel rows to produce the spectrogram. Therefore, the acquisition 900 is divided by the number of available rows to set a spectrum slice interval. If the spectrum slice interval is less than the Spectrum Time, which in this case correlates to each of the time segments, Segment 1 – Segment 10, then processing of each spectral blocks SB1-SB20 includes times from overlapping Spectrum Times. For instance, the spectrum block SB2 in FIG. 9 spans both Time Segment 1 and Time Segment 2 of the original acquisition 900. Ultimately, twenty spectrum blocks, SB1-SB20 are generated from the ten time segments in the acquisition 900, and the twenty spectrum blocks SB1-SB20 each make up a single pixel row of the ultimate spectrogram image. In the example of FIG. 9, there is 50% overlap of the spectrum blocks compared to the original Spectrum Times of the time segments. In practice, the overlap may vary widely, between just over 0% to nearly 100% overlap. A 0% overlap of spectrum blocks is a system where there is no overlap of Spectrum Times across adjacent spectrum blocks, such as the examples described with reference to FIGS. 4, 5, and 8. It should be noted that, although perhaps unlikely, it is also possible that the user has selected time domain settings for the waveform view that require a far smaller slice of time than what is needed to generate the view for the spectrum view. When this occurs, the spectrogram will contain only a single row in the resultant image. Embodiments of the invention may note such a condition to the user by presenting an indication of the condition, such as a color warning, or a text message on the display screen altering the user to the condition.

Providing overlap of the adjacent blocks making up a pixel row of the spectrogram allows for a continuous view of all signal activity of the input signal reflected in the acquired waveform. In other words, unlike systems described above, there are no gaps in the spectrogram where portions of the input signal are missing from the spectrogram created from the acquired waveform.

Further, embodiments according to the disclosure may automatically maximize the size of the spectrogram to fill the spectrogram window as the spectrogram window size is controlled by the user. For example, when the user increases the vertical size of the window containing the spectrogram window, the instrument automatically generates a new spectrogram by increasing the number of lines of pixels in the spectrogram to match the vertical size of the window specified by the user. For example, with reference to FIG. 9, the spectrogram was produced with twenty pixel rows over ten Spectrum Times, for an overlap value of 50%. If the user would increase the size of the window containing the spectrogram, for example to a window that could contain a spectrogram with 30 pixel rows, embodiments of the invention automatically generate a new spectrogram having 30 pixel rows in response to the increased window size. In such a case, the instrument, or more specifically a processor within the instrument, first determines how many pixel rows will fit in the increased window size. In this example, the processor determines that the spectrogram will be maximized within the window with a spectrogram containing 30 pixel rows, and determines that 30 spectrum blocks are needed to perform the maximization, since each pixel row is created from one spectrum block. Next, the processor determines how much each of the individual spectrum blocks overlaps its adjacent spectrum blocks due to the increased number of spectrum blocks in the spectrogram. For instance, with 30 pixel blocks, SB1 – SB30, each adjacent block will overlap its adjacent blocks 66%, which is more than the 50% overlap that was used to produce the spectrogram of FIG. 9. The processor makes the determination by evenly distributing the width of the total number of spectrum blocks over the number of Spectrum Times in the acquired input signal sample, and then determining how much a particular block overlaps its adjacent block. In this example, each spectrum block used to create the spectrogram overlaps its adjacent blocks by 66%. After making such a determination, the processor generates the individual spectrum blocks by combining the spectrums from the individual transforms for each Spectrum Time, as described above. Finally, the processor assembles the new individual spectrum blocks into a new spectrogram, by concatenating the spectrums created by each of the individual spectrum blocks with one another, with each spectral block becoming a single row of the new spectrogram. Then, the processor displays the new spectrogram to match the size of the window specified by the user. When a user shrinks the size of the spectrogram window, the processor performs the same operation, first by determining how many pixel rows will fully fill the smaller window, and then downwardly adjusting the overlap between the number of spectrum blocks used to create each pixel row.

Although this description so far has described creating spectrograms from only a single input channel to a test and measurement instrument, embodiments according to this disclosure may be controlled to generate multiple spectrograms and spectrums, with each spectrogram and spectrum generated from an input waveform sample acquired on a separate input channel of the test and measurement device.

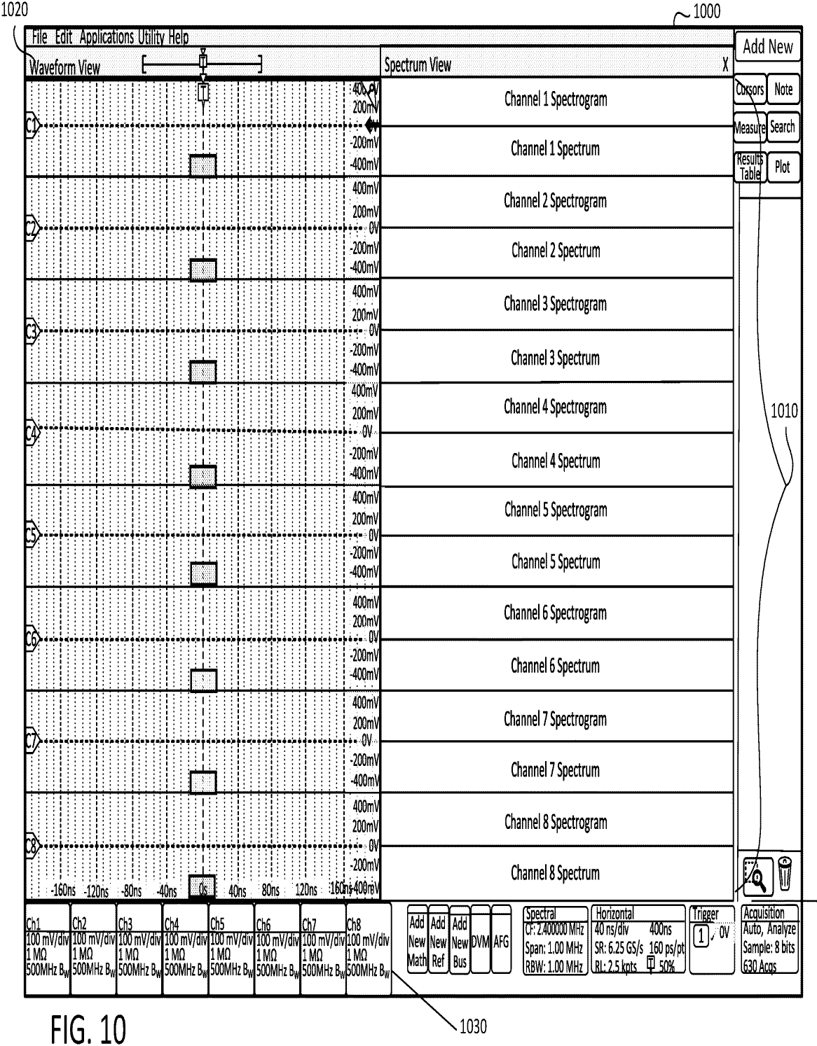

FIG. 10 illustrates an example output screen 1000 showing a spectrum view 1010 that includes multiple channels, according to embodiments of the disclosure. As described above, typically spectrograms are displayed in conjunction with a spectrum, and generally with the spectrogram in an upper portion of the display and the spectrum in the lower portion of the display. The output display screen 1000 shows a spectrum view 1010 that presents spectrograms and spectrum displays for eight separate channels of the test and measurement device simultaneously. Each of the separate channels may be sampling a different signal from the DUT. The separate channels may be triggered from the same event so that the acquisition for each of the separate channels is time aligned to one another. A waveform view 1020 further shows a portion of the input signal for each channel in a time domain. The example output screen 1000 allows a user to see spectrum and spectrogram views from all of the eight separate channels, or however many input channels the test and measurement device has, simultaneously. For example, the spectrum view 1010 shows eight separate channels, with each channel having a spectrogram generated above a spectrum display. A channel badge portion 1030 of the output screen 1000 allows a user to choose or customize which of the input channels are to be displayed on the spectrum view 1010, and in which order the input channels are displayed. A user may choose to display any number of the input channels as spectrograms, in any order.

The spectrum view 1010 of FIG. 10 illustrates a stacked view of the spectrum display. Also, as described above with reference to FIG. 7, a user may change the split between the spectrogram and spectrum for a particular channel by modifying a border of either display, or by manipulating a horizontal indicator between them.

Also, it is possible to upconvert or downconvert signals from particular channels to other channels and display both channels simultaneously for additional testing and measuring. In such an embodiment, the spectrograms for the two channels, for example Channel 1 and Channel 2 span the same frequency, although other display qualities differ. For example, assume a spectrogram of Channel 1 spans from 2.35 GHz to 2.45 GHz, and has a center frequency of 2.4 GHz. Also assume that Channel 2 is the same signal as that acquired on Channel 1, but has been downconverted to 800 MHz. Then, the spectrogram is generated for Channel 2 that is centered at 800 MHz, but spans from 750 MHz to 850 MHz, i.e., the same width as the frequency span for Channel 1. By producing such displays, embodiments of the invention allow for debugging of complex issues that may involve many signals generated simultaneously by a DUT.

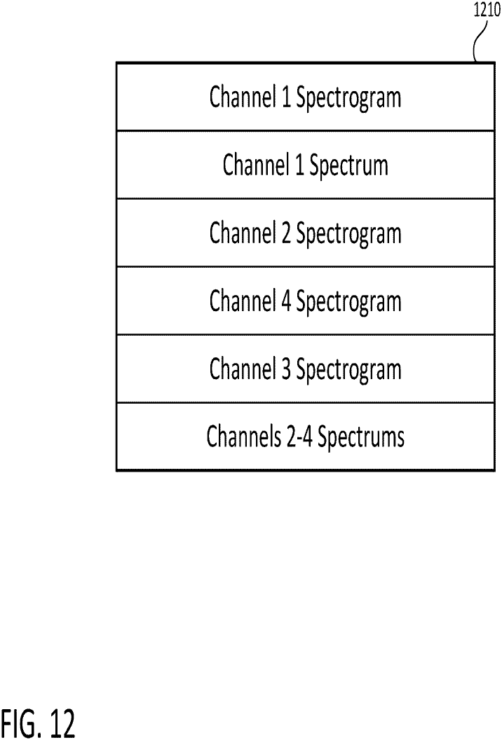

In some embodiments, the user may change the order of the channels shown on the spectrum view 1010 by changing an order of channel badges in the channel badge portion 1030 of the display screen 1000. It is also possible to create groups of channels, which is described with reference to FIG. 12 below.

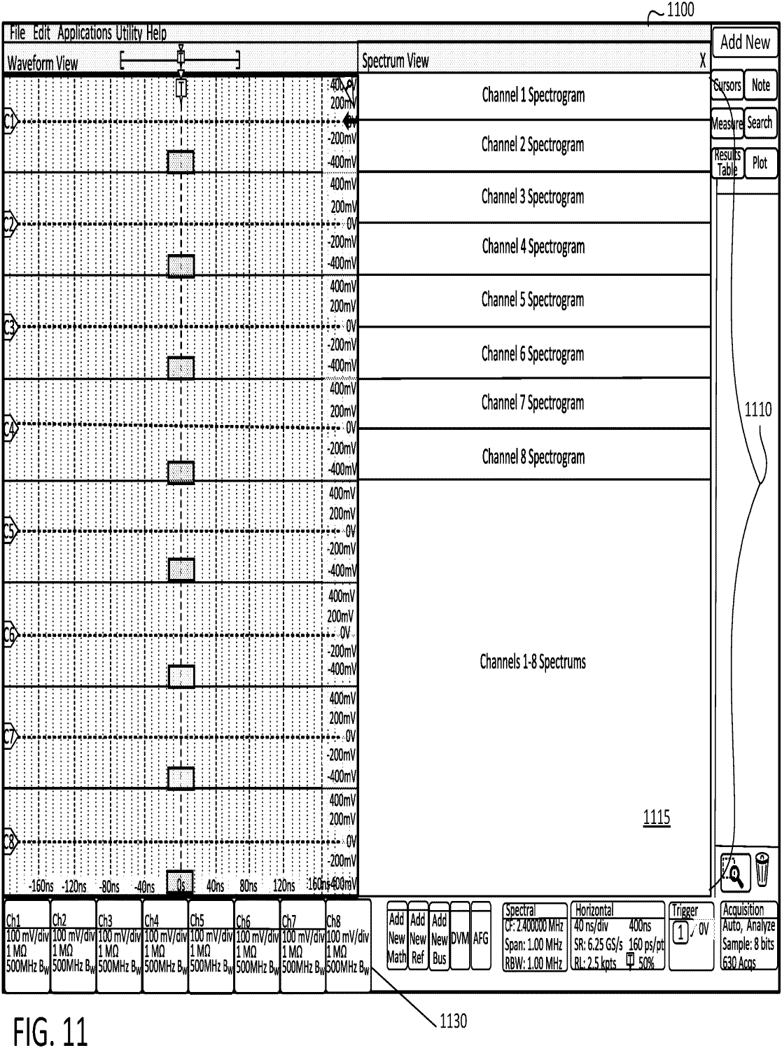

FIG. 11 illustrates another example output screen 1100 showing another spectrum view 1110 illustrating how spectrograms and spectrum displays may be arranged for multiple channels, according to embodiments of the disclosure. Differently than the spectrum view 1010 of FIG. 1, the spectrum view 1110 places each of the spectrograms from Channels 1-8 adjacent to one another, without being adjacent to a spectrum display from the same channel. Instead, in this example, the spectrums for all channels 1-8 are combined into an overlaid spectrum display 1115, which includes all of the Channels 1-8. In FIG. 11, the overlaid spectrum display 1115 is located at the bottom of the spectrum view 1110, but a user may position the spectrum display wherever desired in the spectrum view. Further, as described above, the user may use a channel badge portion 1130 of the example output screen 1100 to select which channels, and in which order, the spectrograms for the selected channels are shown in the spectrum view 1110.

FIG. 12 is a block diagram of only a spectrum view portion 1210 of an example display screen illustrating how various spectrograms and spectrum displays for multiple channels may be grouped, according to embodiments of the disclosure. A user may create a group that includes more than one input channel. For example, in FIG. 12, Channel 1 is not grouped with any other channels, while Channels 2, 3, and 4 are grouped together. The user may create the groups by using the channel badge portion 1130 of FIG. 11, for example. In the illustrated example, spectrograms for the group are displayed adjacent to one another, although the user has directed that the spectrogram for Channel 4 is located between the spectrograms for Channels 2 and 3. Since Channel 1 is not part of the group, its spectrogram and spectrum are shown adjacent to one another. Similarly, since Channels 2, 3, and 4 are grouped, an overlaid spectrum made from each of Channels 2, 3, and 4 is created and appears at the bottom of the spectrum view portion 1210. Embodiments thus allow convenient grouping and ordering of spectrogram and spectrum displays from any of the channels available to the test and measurement instrument.

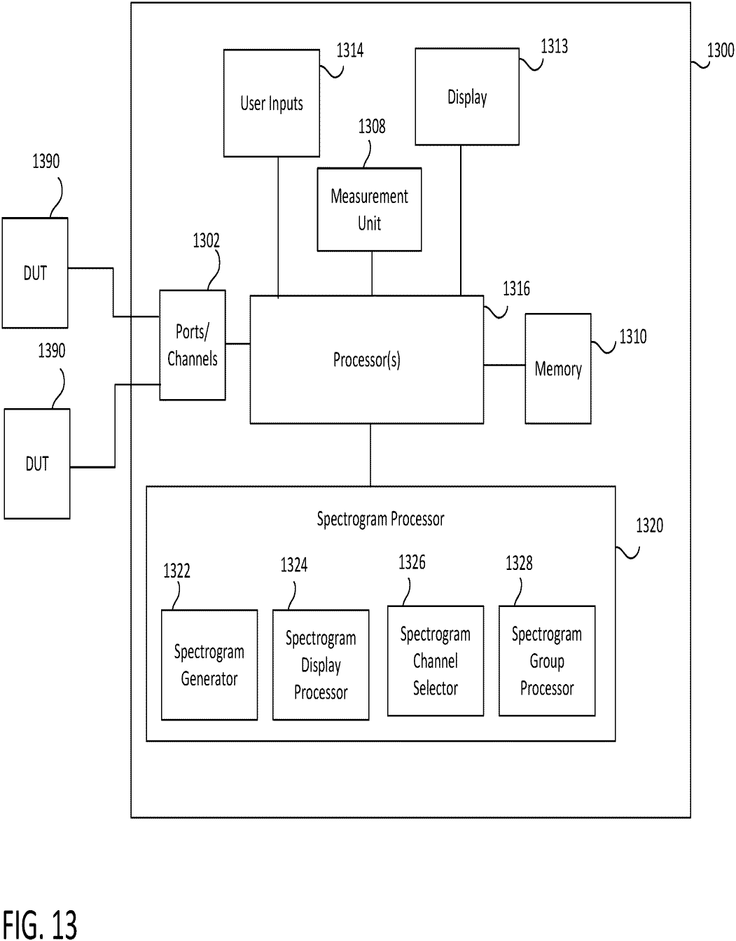

Embodiment of the disclosure operate on particular hardware and/or software to implement the above-described operations. FIG. 13 is a block diagram of an example test and measurement instrument 1300, such as an oscilloscope or spectrum analyzer for implementing embodiments of the disclosure disclosed herein. The test and measurement instrument 1300 includes one or more ports 1302, which may be any electrical signaling medium. The ports 1302 may include receivers, transmitters, and/or transceivers. Each port 1302 is a channel of the test and measurement instrument 1300. The ports 1302 are coupled with one or more processors 1316 to process the signals and/or waveforms received at the ports 1302 from one or more devices under test (DUTs) 1390. Although only one processor 1316 is shown in FIG. 13 for ease of illustration, as will be understood by one skilled in the art, multiple processors 1316 of varying types may be used in combination in the instrument 1300, rather than a single processor 1316.

The ports 1302 can also be connected to a measurement unit 1308 in the test instrument 1300. The measurement unit 1308 can include any component capable of measuring aspects (e.g., voltage, amperage, amplitude, power, energy, etc.) of signals received via ports 1302. The test and measurement instrument 1300 may include additional hardware and/or processors, such as conditioning circuits, analog to digital converters, Fast Fourier Transformers, Chirp-Z Transformers, and/or other circuitry or functions to convert a received signal on any of the channels to a waveform for further analysis. The resulting waveform or various measurements thereof, from each channel, can then be stored in a memory 1310, in an acquisition memory (not illustrated), as well as shown on a display 1312.

The one or more processors 1316 may be configured to execute instructions from the memory 1310 and may perform any methods and/or associated steps indicated by such instructions, such as displaying and modifying the input signals received by the instrument. The memory 1310 may be implemented as processor cache, random access memory (RAM), read only memory (ROM), solid state memory, hard disk drive(s), or any other memory type. The memory 1310 acts as a medium for storing data, computer program products, and other instructions.

User inputs 1314 are coupled to the processor 1316. User inputs 1314 may include a keyboard, mouse, touchscreen, and/or any other controls employable by a user to set up and control the instrument 1300. User inputs 1314 may include a graphical user interface or text/character interface operated in conjunction with the display 1312. User inputs 1314 may further include programmatic inputs from the user on the instrument 1300, or from a remote device. The display 1312 may be a digital screen, a cathode ray tube-based display, or any other monitor to display waveforms, measurements, and other data to a user. While the components of test instrument 1300 are depicted as being integrated within test and measurement instrument 1300, it will be appreciated by a person of ordinary skill in the art that any of these components can be external to test instrument 1300 and can be coupled to test instrument 1300 in any conventional manner (e.g., wired and/or wireless communication media and/or mechanisms). For example, in some embodiments, the display 1312 may be remote from the test and measurement instrument 1300, or the instrument may be configured to send output to a remote device in addition to displaying it on the instrument 1300. In further embodiments, output from the measurement instrument 1300 may be sent to or stored in remote devices, such as cloud devices, that are accessible from other machines coupled to the cloud devices.

The instrument 1300 may include a spectrogram processor 1320, which may be a separate processor from the one or more processors 1316 described above, or the functions of the spectrogram processor 1320 may be integrated into the one or more processors 1316. Additionally, the spectrogram processor 1320 may include separate memory, use the memory 1310 described above, or any other memory accessible by the instrument 1300. The spectrogram processor 1320 may include specialized processors to implement the functions described above. For example, the spectrogram processor 1320 may include a spectrogram generator 1322 used to generate the spectrogram using procedures and operations described above to implement spectrogram generation. A spectrogram display processor 1324 may generate the spectrogram displays to be shown on the display 1312, and may control updating the spectrogram display in real time or near-real time as elements of the display are manipulated by the user, or as the input signal from a DUT 1390 changes. A spectrogram channel selector 1326 controls which of the user-selected channels have spectrograms shown on the display 1313 or remote display, and in which order. A spectrogram group processor 1328 controls the grouping and ordering of the various spectrograms, spectrums, and other displays described above, and both the spectrogram channel selector 1328 and the spectrogram group processor 1328 may work in conjunction with the spectrogram generator 1322 to update the spectrograms in real time or near-real time on the display 1313. Any or all of the components of the spectrogram processor 1320, including the spectrogram generator 1322, spectrogram display processor 1324, spectrogram channel selector 1326, and/or spectrogram group processor 1328 may be embodied in one or more separate processors, and the separate functionality described herein may be implemented as specific preprogrammed operations of a special purpose or general purpose processor. Further, as stated above, any or all of the components or functionality of the spectrogram processor 1320 may be integrated into the one or more processors 1316 that operate the instrument 1300.

Further, particular aspects of the disclosure may operate on a particularly created hardware, on firmware, digital signal processors, or on a specially programmed general-purpose computer including a processor operating according to programmed instructions. The terms controller or processor as used herein are intended to include microprocessors, microcomputers, Application Specific Integrated Circuits (ASICs), and dedicated hardware controllers. One or more aspects of the disclosure may be embodied in computer-usable data and computer-executable instructions, such as in one or more program modules, executed by one or more computers (including monitoring modules), or other devices. Generally, program modules include routines, programs, objects, components, data structures, etc. that perform particular tasks or implement particular abstract data types when executed by a processor in a computer or other device. The computer executable instructions may be stored on a non-transitory computer readable medium such as a hard disk, optical disk, removable storage media, solid state memory, Random Access Memory (RAM), etc. As will be appreciated by one of skill in the art, the functionality of the program modules may be combined or distributed as desired in various aspects. In addition, the functionality may be embodied in whole or in part in firmware or hardware equivalents such as integrated circuits, FPGA, and the like. Particular data structures may be used to more effectively implement one or more aspects of the disclosure, and such data structures are contemplated within the scope of computer executable instructions and computer-usable data described herein.

Computer storage media means any medium that can be used to store computer-readable information. By way of example, and not limitation, computer storage media may include RAM, ROM, Electrically Erasable Programmable Read-Only Memory (EEPROM), flash memory or other memory technology, Compact Disc Read Only Memory (CD-ROM), Digital Video Disc (DVD), or other optical disk storage, magnetic cassettes, magnetic tape, magnetic disk storage or other magnetic storage devices, and any other volatile or nonvolatile, removable or non-removable media implemented in any technology. Computer storage media excludes signals per se and transitory forms of signal transmission.

Communication media means any media that can be used for the communication of computer-readable information. By way of example, and not limitation, communication media may include coaxial cables, fiber-optic cables, air, or any other media suitable for the communication of electrical, optical, Radio Frequency (RF), infrared, acoustic or other types of signals.

### EXAMPLES

Illustrative examples of the disclosed technologies are provided below. An embodiment of the technologies may include one or more, and any combination of, the examples described below.

Example 1 is a test and measurement instrument, including a first channel input for accepting a first input signal, a second channel input for accepting a second input signal, a spectrogram processor for producing a first spectrogram from the first input signal and for producing a second spectrogram from the second input signal, and a display for simultaneously showing the first spectrogram and the second spectrogram.

Example 2 is a test and measurement instrument according to Example 1, in which the first spectrogram and the second spectrogram are vertically aligned on the display.

Example 3 is a test and measurement instrument according to any of the preceding Examples, in which the first spectrogram and the second spectrogram have the same frequency span.

Example 4 is a test and measurement instrument according to any of the preceding Examples, in which the first spectrogram and the second spectrogram have a different center frequency.

Example 5 is a test and measurement instrument according to any of the preceding Examples, in which the first spectrogram and the second spectrograms are continuous spectrograms.

Example 6 is a test and measurement instrument according to any of the preceding Examples, further including a spectrum display generated from a portion of the first input signal that is shown on the display adjacent to the first spectrogram.

Example 7 is a test and measurement instrument according to any of the preceding Examples, further including a first spectrum display generated from a portion of the first input signal and a second spectrum display generated from a portion of the second input signal, in which the first spectrum display is shown on the display adjacent to the first spectrogram and in which the second spectrum display shown on the display is adjacent to the second spectrogram.

Example 8 is a test and measurement instrument according to Example 7, in which locations of the first spectrogram, the second spectrogram, first spectrum display, and the second spectrum display are independently positionable on the display by a user.

Example 9 is a test and measurement instrument according to any of the preceding Examples, further including a third channel input for accepting a third input signal, in which the spectrogram processor is structured to produce a third spectrogram from the third input signal.

Example 10 is a test and measurement instrument according to Example 9, in which the display is structured to show a spectrum display generated from a combination of individual spectrums from the second input signal and the third input signal, but not including an individual spectrum from the first input signal.

Example 11 is a method in a test and measurement instrument, the method including accepting a first input signal from a first input channel, accepting a second input signal from a second input channel, producing a first spectrogram from the first input signal and a second spectrogram from the second input signal, and simultaneously showing the first spectrogram and the second spectrogram on a display.

Example 12 is a method according to Example 11, in which the first spectrogram and the second spectrogram are vertically aligned on the display.

Example 13 is a method according to any of the preceding Example methods, in which the first spectrogram and the second spectrogram have the same frequency span.

Example 14 is a method according to any of the preceding Example methods, in which the first spectrogram and the second spectrogram have a different center frequency.

Example 15 is a method according to any of the preceding Example methods, in which the first spectrogram and the second spectrograms are continuous spectrograms.

Example 16 is a method according to any of the preceding Example methods, further including generating a spectrum display from a portion of the first input signal, and showing the spectrum display on the display adjacent the first spectrogram.

Example 17 is a method according to any of the preceding Example methods, further including generating a first spectrum display from a portion of the first input signal, generating a second spectrum display from a portion of the second input signal, showing the first spectrum display on the display adjacent to the first spectrogram, and showing the second spectrum display on the display adjacent to the second spectrogram.

Example 18 is a method according to Example 17, further including accepting input from a user of the test and measurement device to reposition any of the first spectrogram, the second spectrogram, first spectrum display, and the second spectrum display on the display.

Example 19 is a method according to any of the preceding Example methods, further including accepting a third input signal from a third input channel, and producing a third spectrogram from the third input signal.

Example 20 is a method according to Example 19, further including generating an overlaid spectrum display from a combination of individual spectrums from the second input signal and the third input signal, but not including an individual spectrum from the first input signal, displaying the overlaid spectrum display on the display.

The previously described versions of the disclosed subject matter have many advantages that were either described or would be apparent to a person of ordinary skill. Even so, these advantages or features are not required in all versions of the disclosed apparatus, systems, or methods.

Also, when reference is made in this application to a method having two or more defined steps or operations, the defined steps or operations can be carried out in any order or simultaneously, unless the context excludes those possibilities.

Additionally, this written description makes reference to particular features. It is to be understood that the disclosure in this specification includes all possible combinations of those particular features. Where a particular feature is disclosed in the context of a particular aspect or example, that feature can also be used, to the extent possible, in the context of other aspects and examples.

All features disclosed in the specification, including the claims, abstract, and drawings, and all the steps in any method or process disclosed, may be combined in any combination, except combinations where at least some of such features and/or steps are mutually exclusive. Each feature disclosed in the specification, including the claims, abstract, and drawings, can be replaced by alternative features serving the same, equivalent, or similar purpose, unless expressly stated otherwise.

Although specific examples of the invention have been illustrated and described for purposes of illustration, it will be understood that various modifications may be made without departing from the spirit and scope of the invention. Accordingly, the invention should not be limited except as by the appended claims.

We claim:

1. A test and measurement instrument, comprising:
a first channel input for accepting a first input signal;
a second channel input for accepting a second input signal;
a spectrogram processor for producing a first spectrogram from the first input signal and for producing a second spectrogram from the second input signal; and
a display for simultaneously showing the first spectrogram and the second spectrogram.

2. The test and measurement instrument according to claim 1, in which the first spectrogram and the second spectrogram are vertically aligned on the display.

3. The test and measurement instrument according to claim 1, in which the first spectrogram and the second spectrogram have the same frequency span.

4. The test and measurement instrument according to claim 1, in which the first spectrogram and the second spectrogram have a different center frequency.

5. The test and measurement instrument according to claim 1, in which the first spectrogram and the second spectrograms are continuous spectrograms.

6. The test and measurement instrument according to claim 1, further comprising a spectrum display generated from a portion of the first input signal that is shown on the display adjacent to the first spectrogram.

7. The test and measurement instrument according to claim 1, further comprising a first spectrum display generated from a portion of the first input signal and a second spectrum display generated from a portion of the second input signal, in which the first spectrum display is shown on the display adjacent to the first spectrogram and in which the second spectrum display shown on the display is adjacent to the second spectrogram.

8. The test and measurement instrument according to claim 7, in which locations of the first spectrogram, the second spectrogram, first spectrum display, and the second spectrum display are independently positionable on the display by a user.

9. The test and measurement instrument according to claim 1, further comprising a third channel input for accepting a third input signal, in which the spectrogram processor is structured to produce a third spectrogram from the third input signal.

10. The test and measurement instrument according to claim 9, in which the display is structured to show a spectrum display generated from a combination of individual spectrums from the second input signal and the third input signal, but not including an individual spectrum from the first input signal.

11. A method in a test and measurement instrument, the method comprising:
accepting a first input signal from a first input channel;
accepting a second input signal from a second input channel;
producing a first spectrogram from the first input signal and a second spectrogram from the second input signal; and
simultaneously showing the first spectrogram and the second spectrogram on a display.

12. The method according to claim 11, in which the first spectrogram and the second spectrogram are vertically aligned on the display.

13. The method according to claim 11, in which the first spectrogram and the second spectrogram have the same frequency span.

14. The method according to claim 11, in which the first spectrogram and the second spectrogram have a different center frequency.

15. The method according to claim 11, in which the first spectrogram and the second spectrograms are continuous spectrograms.

16. The method according to claim 11, further comprising:
generating a spectrum display from a portion of the first input signal; and
showing the spectrum display on the display adjacent the first spectrogram.

17. The method according to claim 11, further comprising:
generating a first spectrum display from a portion of the first input signal;
generating a second spectrum display from a portion of the second input signal;
showing the first spectrum display on the display adjacent to the first spectrogram; and
showing the second spectrum display on the display adjacent to the second spectrogram.

18. The method according to claim 17, further comprising accepting input from a user of the test and measurement device to reposition any of the first spectrogram, the second spectrogram, first spectrum display, and the second spectrum display on the display.

19. The method according to claim 11, further comprising:
accepting a third input signal from a third input channel; and
producing a third spectrogram from the third input signal.

20. The method according to claim 19, further comprising:
generating an overlaid spectrum display from a combination of individual spectrums from the second input signal and the third input signal, but not including an individual spectrum from the first input signal; and
displaying the overlaid spectrum display on the display.
